(19) United States
(12) Patent Application Publication
(10) Pub. No.: US 2023/0268470 A1
(43) Pub. Date: Aug. 24, 2023

(54) DISPLAY DEVICE

(71) Applicant: Innolux Corporation, Miaoli County (TW)

(72) Inventors: Shu-Ming Kuo, Miaoli County (TW); Tsau-Hua Hsieh, Miaoli County (TW)

(73) Assignee: Innolux Corporation, Miaoli County (TW)

(21) Appl. No.: 18/153,984

(22) Filed: Jan. 12, 2023

(30) Foreign Application Priority Data
Feb. 22, 2022 (CN) 202210164116.3

(51) Int. Cl. H01L 33/50; H01L 25/16

(52) U.S. Cl. CPC H01L 33/507; H01L 25/167

(57) ABSTRACT

A display device includes a substrate, a first light-emitting unit, a first band-pass filter, and a first light conversion layer. The first light-emitting unit is disposed on the substrate and configured to emit a first light beam. The first band-pass filter is disposed on the first light-emitting unit and has a first cut-off wavelength. The first light conversion layer is disposed on the first band-pass filter and configured to convert the first light beam into a first conversion light beam. The first conversion light beam has a first peak wavelength. A difference between the first cut-off wavelength and the first peak wavelength is less than 10% of the first peak wavelength.

### CROSS-REFERENCE TO RELATED APPLICATION

This application claims the priority benefit of China application serial no. 202210164116.3, filed on Feb. 22, 2022. The entirety of the above-mentioned patent application is hereby incorporated by reference herein and made a part of this specification.

### BACKGROUND

### Technical Field

The disclosure relates to an electronic device, and more particularly, to a display device.

### Description of Related Art

In a display device, a light-emitting characteristic of a light-emitting element and a light conversion material is Lambertian, which causes leakage and waste of a large amount of light in a panel structure, resulting in poor light conversion efficiency.

### SUMMARY

The disclosure is directed to a display device, which has good light conversion efficiency.

According to an embodiment of the disclosure, the display device includes a substrate, a first light-emitting unit, a first band-pass filter, and a first light conversion layer. The first light-emitting unit is disposed on the substrate and configured to emit a first light beam. The first band-pass filter is disposed on the first light-emitting unit and has a first cut-off wavelength. The first light conversion layer is disposed on the first band-pass filter and configured to convert the first light beam into a first conversion light beam. The first conversion light beam has a first peak wavelength. A difference between the first cut-off wavelength and the first peak wavelength is less than 10% of the first peak wavelength.

According to an embodiment of the disclosure, the display device includes a substrate, a first light-emitting unit, a second light-emitting unit, a band-pass filter, and a light conversion layer. The first light-emitting unit is disposed on the substrate and configured to emit a first light beam. The second light-emitting unit is disposed on the substrate and configured to emit a second light beam. The first light beam and the second light beam have different colors, and the second light beam has a first peak wavelength. The band-pass filter is disposed on the first light-emitting unit and the second light-emitting unit and has a cut-off wavelength. The light conversion layer is disposed on the band-pass filter and configured to convert the first light beam into a first conversion light beam. The first conversion light beam has a second peak wavelength, and the cut-off wavelength is between the first peak wavelength and the second peak wavelength.

In order for the aforementioned features and advantages of the disclosure to be more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1, FIG. 5, FIG. 6, FIG. 7, FIG. 8, FIG. 9, FIG. 10, FIG. 11A, and FIG. 12A are respectively partial cross-sectional schematic views of display devices according to some embodiments of the disclosure.

FIG. 2, FIG. 4, and FIG. 11B are respectively a wavelength-transmissivity curve of a band-pass filter.

FIG. 3 is a wavelength-reflectivity curve of the band-pass filter.

FIG. 12B is an angle-light intensity curve of a light beam after passing through the band-pass filter.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

Throughout this disclosure and the appended claims, certain terms may be used to refer to particular components. Those skilled in the art should understand that electronic device manufacturers may refer to the same components by different names. This specification does not intend to distinguish between components that have the same function but have different names. In the following description and claims, words such as “containing” and “comprising” are open-ended words, so they should be interpreted as meaning “including but not limited to . . . ”.

The directional terms mentioned in this specification, such as “up”, “down”, “front”, “rear”, “left”, “right”, etc., only refer to the directions of the drawings. Therefore, the used directional terminology is illustrative, and is not used for limiting the disclosure. In the drawings, various figures illustrate the general characteristics of methods, structures and/or materials used in particular embodiments. However, these drawings should not be construed to define or limit the scope or nature encompassed by these embodiments. For example, the relative sizes, thicknesses and positions of various layers, regions and/or structures may be reduced or exaggerated for clarity's sake.

One structure (or layer, element, substrate) described in the disclosure is located on/above another structure (or layer, element, substrate), which means that the two structures are adjacent and in direct connection, or means that the two structures are adjacent but in indirect connection. Indirect connection means that there is at least one intermediate structure (or intermediate layer, intermediate element, intermediate substrate, intermediate space) between the two structures, a lower surface of a structure is adjacent or directly connected to an upper surface of the intermediate structure, and an upper surface of the other structure is adjacent to or directly connected to a lower surface of the intermediate structure. The intermediary structure may be composed of a single-layer or multi-layer physical structure or non-physical structure, which is not limited by the disclosure. In the disclosure, when a certain structure is described to be “on” another structure, it means that the certain structure is “directly” on the another structure, or means that the certain structure is “indirectly” on the another structure, i.e., at least one structure is further clamped between the certain structure and the another structure.

The terms “about”, “equal to”, “equal” or “same”, “substantially” or “approximately” are generally interpreted as being within 20% of a given value or range, or interpreted as being within 10%, 5%, 3%, 2%, 1%, or 0.5% of the given value or range.

The ordinal numbers used in the specification and claims, such as “first”, “second”, etc., are used to modify components, and do not imply and represent that the component or these components have any previous ordinal numbers, and do not represent a sequence of one component with another, or a sequence in a manufacturing method. The use of these ordinal numbers is only to make a clear distinction between one component with a certain name and another component with the same name. The same terms may not be used in the claims and the specification, and accordingly, a first component in the specification may be a second component in the claims.

The electrical connection or coupling described in this disclosure may refer to direct connection or indirect connection. In the case of direct connection, terminals of components on two circuits are directly connected or connected to each other by a conductor line segment, and in the case of indirect connection, there are switches, diodes, capacitors, inductors, resistors, other suitable components, or a combination of the above components between the terminals of the components on the two circuits, but the disclosure is not limited thereto.

In the disclosure, a thickness, length, width, and area may be measured by using an optical microscope, and the thickness may be obtained by measuring a cross-sectional image in the electron microscope, but the disclosure is not limited thereto. In addition, there may be a certain error in any two values or directions used for comparison. In addition, the terms “equal to”, “equal”, “same”, “substantially” or “approximately” mentioned in the present disclosure usually represent within 10% of a given value or range. Moreover, the expressions “the given range is a first value to a second value”, “the given range falls within a range of the first value to the second value” mean that the given range includes the first value, the second value, and other values there between. If a first direction is perpendicular to a second direction, an angle between the first direction and the second direction may be between 80 degrees and 100 degrees; and if the first direction is parallel to the second direction, the angle between the first direction and the second direction may be between 0 degree and 10 degrees.

It should be noted that in the following embodiments, features in a plurality of different embodiments may be substituted, reorganized, and mixed to complete other embodiments without departing from the spirit of the present disclosure. The features of the various embodiments may be mixed and matched arbitrarily as long as they do not violate or conflict with the spirit of the disclosure.

Unless otherwise defined, all terms (including technical and scientific terms) used herein have the same meanings as commonly understood by those skilled in the art to which this disclosure belongs. It is understandable that these terms, such as those defined in commonly used dictionaries, should be interpreted as having meaning consistent with the relevant technology and the background or context of this disclosure, and should not be interpreted in an idealized or excessively formal way, unless there is a special definition in the embodiment of the disclosure.

In the disclosure, the electronic device may include a display device, a backlight device, an antenna device, a sensing device, or a splicing device, but the disclosure is not limited thereto. The electronic device may be a bendable or flexible electronic device. The display device may be a non-self-luminous type display device or a self-luminous type display device. The antenna device may be a liquid crystal type antenna device or a non-liquid crystal type antenna device, and the sensing device may be a sensing device that senses capacitance, light, heat, or ultrasound, but the disclosure is not limited thereto. In the disclosure, the electronic device may include electronic components, and the electronic components may include passive components and active components, such as capacitors, resistors, inductors, diodes, transistors, etc. The diode may include a light-emitting diode or a photodiode. The light-emitting diode may include, for example, an organic light-emitting diode (OLED), a mini LED, a micro LED or a quantum dot LED, but the disclosure is not limited thereto. The splicing device may be, for example, a display splicing device or an antenna splicing device, but the disclosure is not limited thereto. It should be noted that the electronic device may be any arrangement and combination of the foregoing, but the disclosure is not limited thereto. In the following descriptions, a display device is used as an electronic device or a splicing device to describe the content of the disclosure, but the disclosure is not limited thereto.

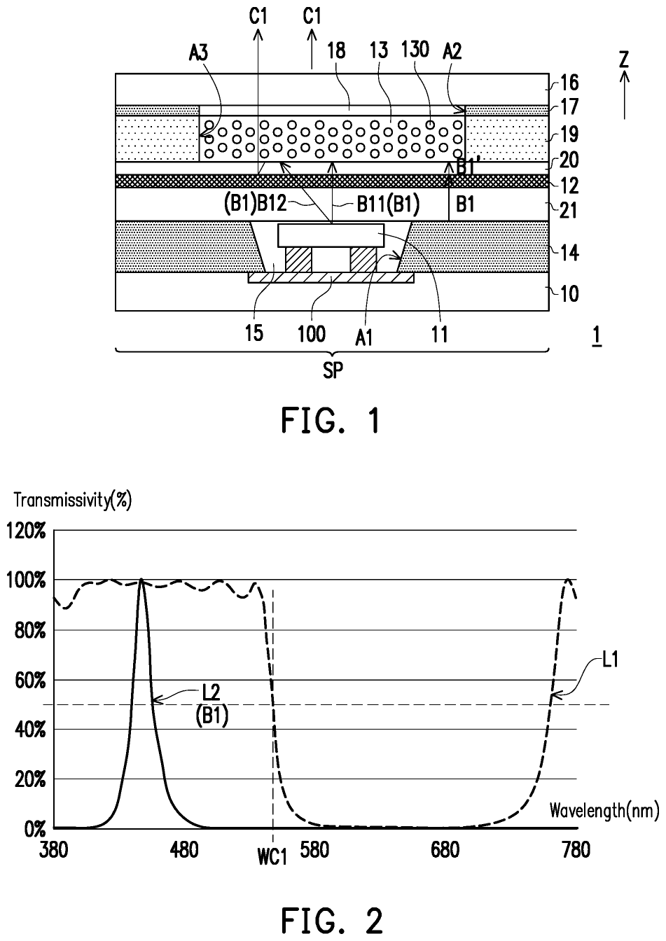

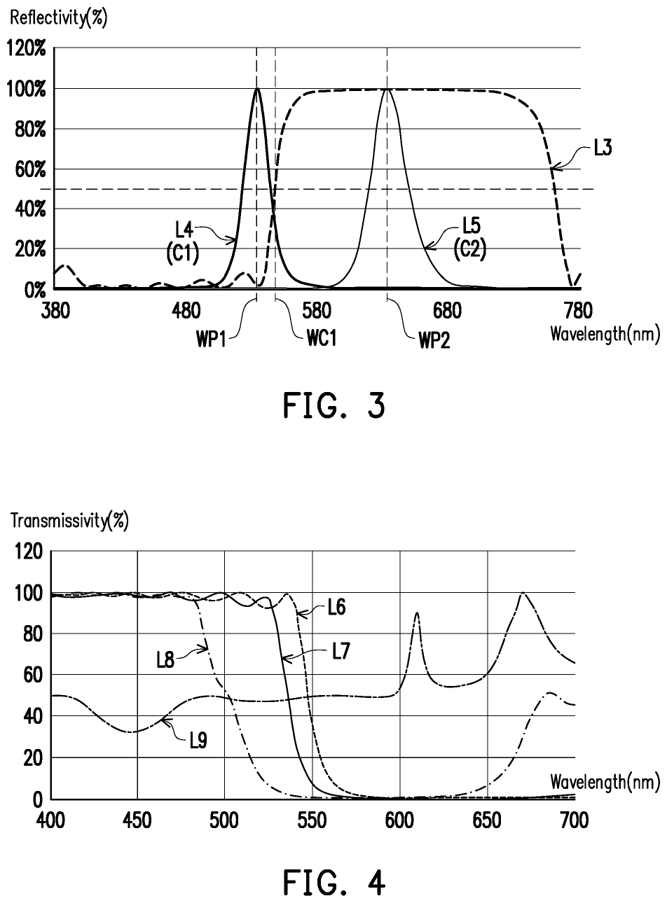

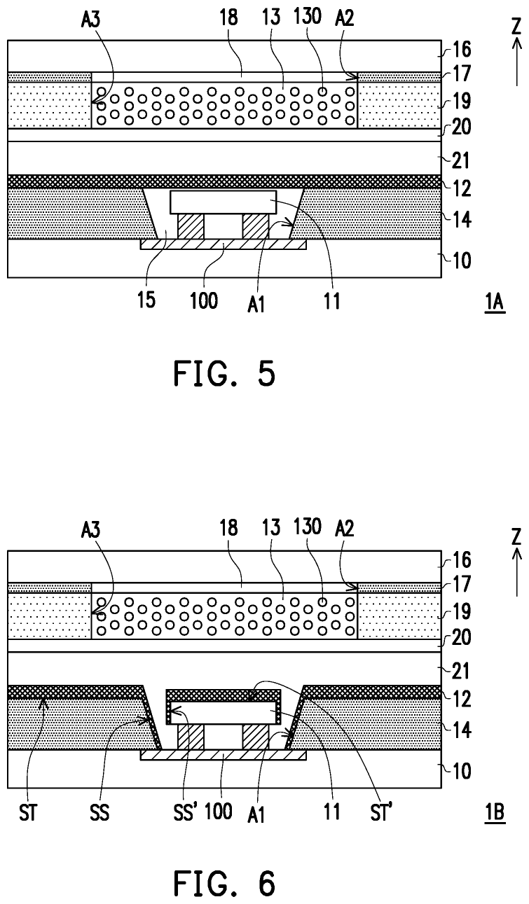

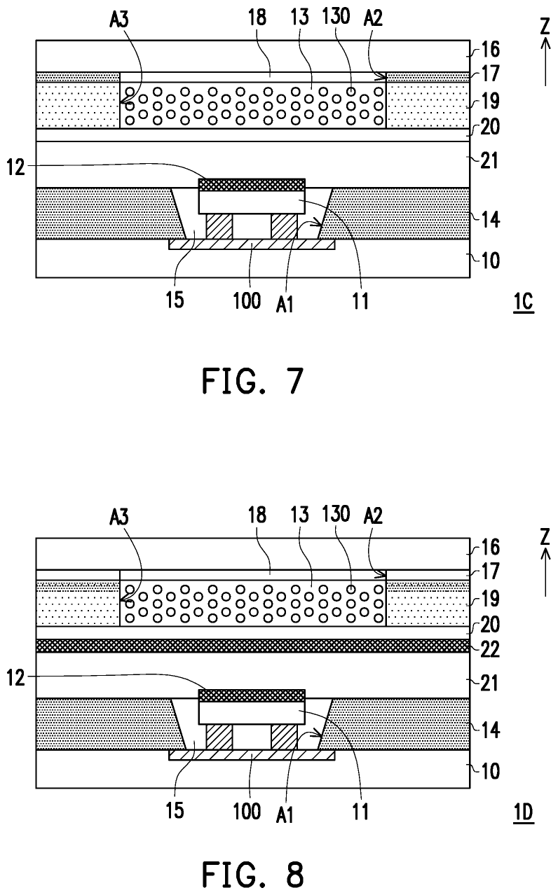

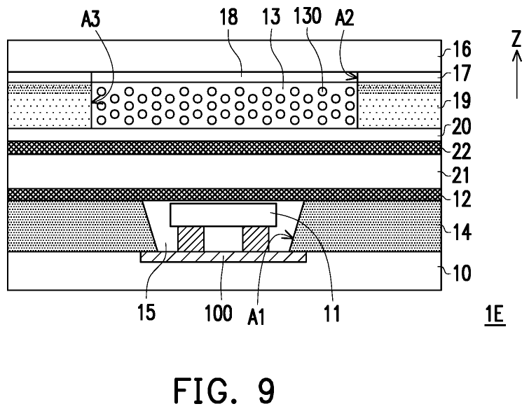

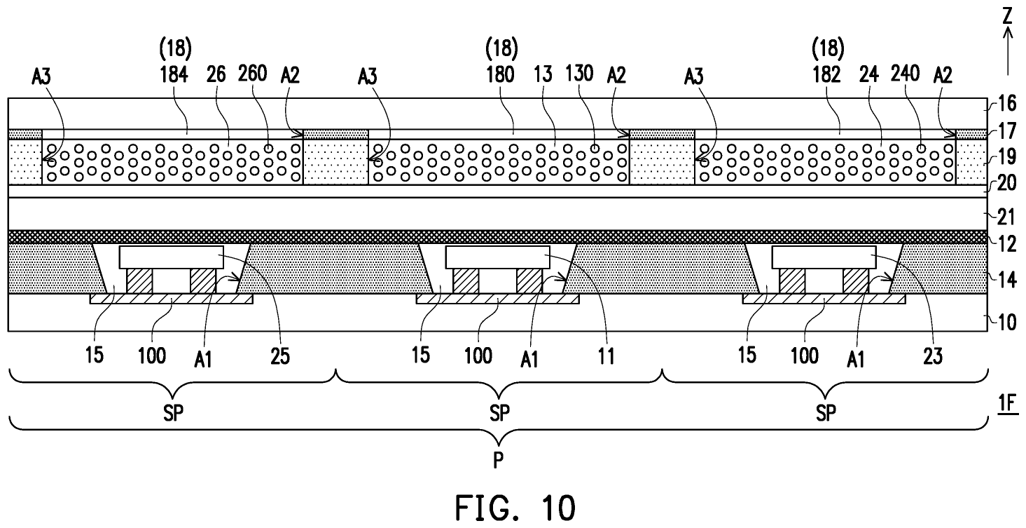

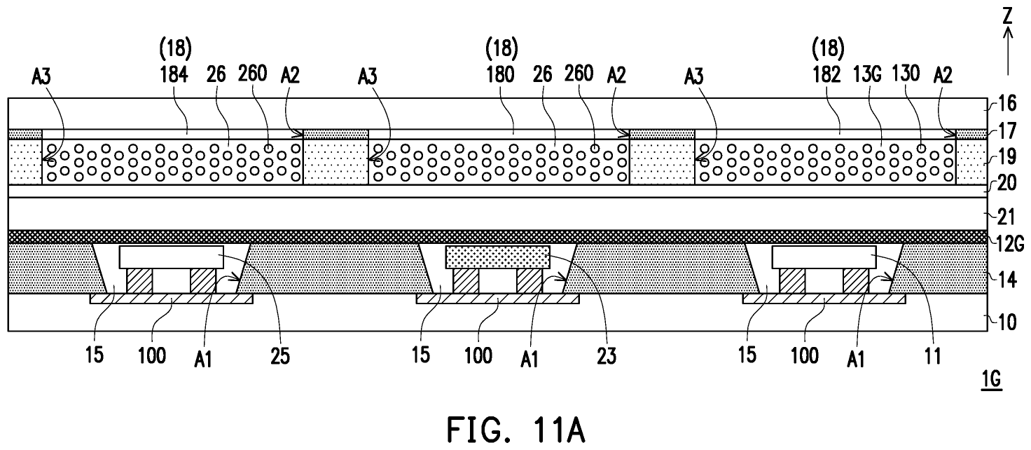

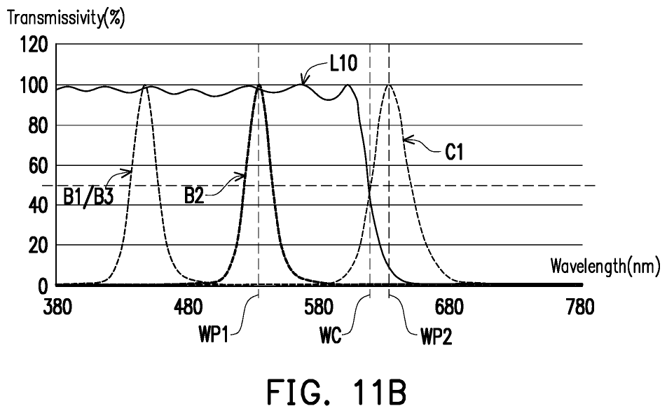

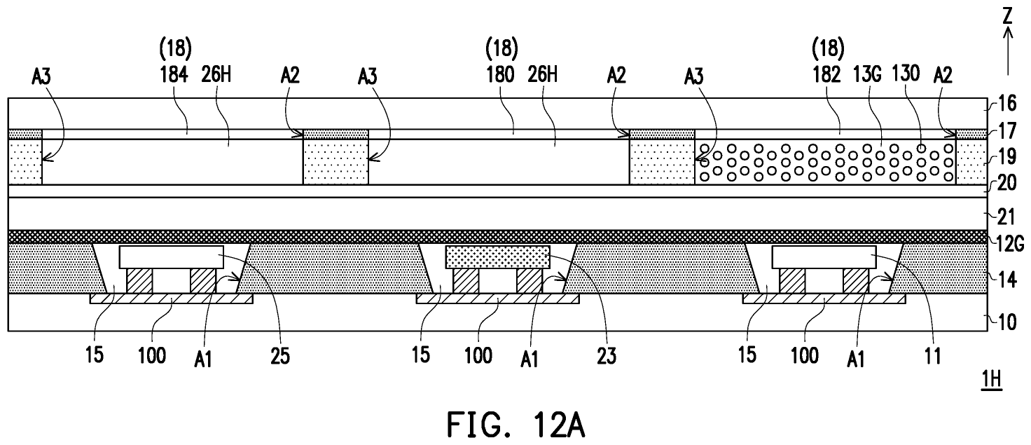

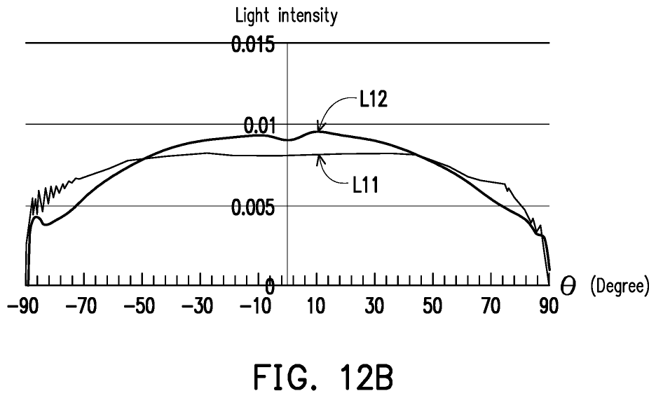

FIG. 1, FIG. 5 to FIG. 11A and FIG. 12A are respectively partial cross-sectional schematic views of display devices according to some embodiments of the disclosure. FIG. 2, FIG. 4, and FIG. 11B are respectively a wavelength-transmissivity curve of a band-pass filter. FIG. 3 is a wavelength-reflectivity curve of the band-pass filter. FIG. 12B is an angle-light intensity curve of a light beam after passing through the band-pass filter. It should be noted that the technical solutions provided by the different embodiments hereinafter may be replaced, combined or used in combination, so as to constitute another embodiment without violating the spirit of the disclosure.

Referring to FIG. 1, a display device 1 may include a substrate 10, a first light-emitting unit 11, a first band-pass filter 12 and a first light conversion layer 13. The first light-emitting unit 11 is disposed on the substrate 10 and configured to emit a first light beam B1. The first light beam B1 is light emitted by a light-emitting unit (for example, the first light-emitting unit 11) under a single sub-pixel SP in a single pixel P (not shown in FIG. 1, please referring to FIG. 10). For example, a wavelength of the first light beam B1 may be 430 nm to 470 nm. The first band-pass filter 12 is disposed on the first light-emitting unit 11 and has a first cut-off wavelength WC1. In some embodiments, the first light beam B1 may become a first light beam B1′ after passing through the first band-pass filter 12. The first light beam B1′ may have the same or similar waveform and wavelength as the first light beam B1. The first light conversion layer 13 is disposed on the first band-pass filter 12 and configured to convert the first light beam B1/first light beam BP into a first conversion light beam C1. The first conversion light beam C1 is the light transmitted to the user after passing through all light-emitting structures under the single sub-pixel SP in the single pixel. The first conversion light beam C1 may be a red light beam, a green light beam or a blue light beam, and a wavelength of the first conversion light beam C1 may be a wavelength corresponding to a red light beam, a green light beam or a blue light beam. For example, the wavelength of the first conversion light beam C1 may be 520 nm to 550 nm.

In detail, the substrate 10 may include a circuit board or a carrier board with circuits formed thereon, but the disclosure is not limited thereto. The circuit board may include a printed circuit board, a flexible printed circuit board, etc., but the disclosure is not limited thereto. A material of the carrier board may include glass, plastic, ceramic, quartz, sapphire, or a combination of the above materials, but the disclosure is not limited thereto. In some embodiments, the electronic device 1 may further include a reflector 100. The reflector 100 is disposed under the first light-emitting unit 11 to turn the first light beam B1 transmitted toward the substrate 10, so that the first light beam B1 is transferred to the first light conversion layer 13. For example, a reflective pattern may be additionally formed on the substrate 10 to serve as the reflector 100.

The first light-emitting unit 11 may be fixed on the substrate 10 by soldering, adhering or any feasible bonding method, and is electrically connected to an external circuit (such as a power source) through a circuit (not shown) on the substrate 10, thereby providing the first light beam B1. The first light beam B1 is, for example, blue, but the disclosure is not limited thereto. The first light-emitting unit 11 may include a light-emitting diode, such as an organic light-emitting diode, a mini light-emitting diode, a micro light-emitting diode or a quantum dot light-emitting diode, but the disclosure is not limited thereto. In some embodiments, the first light-emitting unit 11 may include a light-emitting diode die. In other embodiments, the first light-emitting unit 11 may include a packaged light-emitting diode, but the disclosure is not limited thereto. In some embodiments, although not shown, the display device 1 may include a plurality of first light-emitting units 11, and the plurality of first light-emitting units 11 may be arranged in an array on the substrate 10 to provide a planar light source.

The first band-pass filter 12 may transmit light of a specific waveband and reflect light of other wavebands. For example, the first band-pass filter 12 may be designed to allow the first light beam B1 emitted by the first light-emitting unit 11 to pass through, so that most of the first light beam B1 may be transmitted to the first light conversion layer 13 to generate the first conversion light beam C1. Furthermore, the first band-pass filter 12 may be designed to reflect at least a part of the first conversion light beam C1 converted by the first light conversion layer 13, so that the first conversion light beam C1 transmitted toward the first band-pass filter 12 may be reflected by the first band-pass filter 12 to have a chance to exit from the display device 1. Thereby, a light utilization rate or light conversion efficiency is improved. In some embodiments, the first band-pass filter 12 may include a multilayer film, such as alternating stacked layers of multilayer high refractive index layers and multilayer low refractive index layers, but the disclosure is not limited thereto. In some other embodiments, the first band-pass filter 12 may include a distributed Bragg reflector (DBR), but the disclosure is not limited thereto.

The first light conversion layer 13 may include a wavelength conversion material. The wavelength conversion material may be excited by a light beam of one wavelength (for example, the first light beam B1), and convert the light beam of such wavelength into a light beam of another wavelength (for example, the first conversion light beam C1). The wavelength conversion material may include fluorescence, phosphor, quantum dots (QD), other suitable materials, or a combination of the above materials, but the disclosure is not limited thereto. In some embodiments, the first light conversion layer 13 may further include light scattering particles 130 to increase a transmission path of the first light beam B1 in the first light conversion layer 13, so that more of the first light beam B1 is converted into the first conversion light beam C1 by the wavelength conversion material, but the disclosure is not limited thereto.

Referring to FIG. 2, a curve L1, for example, represents transmissivity of the first band-pass filter 12 in a visible light waveband (such as light with a wavelength falls between 380 nm and 780 nm) with respect to the light incident (such as normal incidence) to the first band-pass filter 12, and a curve L2, for example, represents a spectrum of the first light beam B1 (for example, the blue light beam) emitted by the first light-emitting unit 11 (for example, the blue light-emitting unit). By making the spectrum of the first light beam B1 falling within a transmission wavelength range of the first band-pass filter 12, most of the first light beam B1 may pass through the first band-pass filter 12 and may be transmitted to the first light conversion layer 13.

Referring to FIG. 3, a curve L3, for example, represents reflectivity of the first band-pass filter 12 in the visible light waveband with respect to the light incident (for example, normal incidence) to the first band-pass filter 12, a curve L4, for example, represents a spectrum of the first conversion light beam C1 (for example, a green light beam) converted by the first light conversion layer 13 (for example, a green light conversion layer), and a curve L5, for example, represents a spectrum of a conversion light beam (for example, a red light beam) converted by another light conversion layer (not shown, for example, a red light conversion layer). By making the spectrum of the conversion light beams (such as the first conversion light beam C1 and the red light beam) falling within a reflection wavelength range of the first band-pass filter 12, most of the conversion light beams may be reflected by the first band-pass filter 12 to have a change to emit from the display device 1. The first conversion light beam C1 has a first peak wavelength WP1. The first peak wavelength WP1 refers to a wavelength corresponding to the maximum peak with the highest grayscale (such as 255 grayscale) or the maximum light intensity in the wavelength range (such as 520 nm to 550 nm) of the first conversion light beam C1. A difference between the first cut-off wavelength WC1 and the first peak wavelength WP1 is less than 10% of the first peak wavelength WP1.

Referring to FIG. 4, multiple curves in FIG. 4 respectively represent the transmissivities of light incident to the first band-pass filter 12 at different incident angles. The incident angle is defined as an angle between a light traveling direction and a normal line of a lower surface of the first band-pass filter 12. An incident angle of 0 degree means that a light beam is incident to the first band-pass filter 12 perpendicularly, as shown by a light beam B11 in FIG. 1. If an incident angle is not 0 degree, it means that the light beam is incident to the first band-pass filter 12 obliquely, as shown by a light beam B12 in FIG. 1. Incident angles corresponding to a curve L6, a curve L7, a curve L8 and a curve L9 are respectively 0 degree, 15 degrees, 30 degrees and 45 degrees.

As shown in FIG. 4, the transmissivity (or reflectivity) of the first band-pass filter 12 shifts to a short wavelength (i.e., blue shift) along with the increase of the incident angle, i.e., the transmissivity of the first band-pass filter 12 to the first light beam B1 decreases as the incident angle of the first light beam B1 increases, which results in a decrease in the amount of the first light beam B1 transmitted to the first light conversion layer 13 and a decrease in light conversion efficiency.

In the embodiment, by shifting the transmissivity of the first band-pass filter 12 to a long wavelength (i.e., red shift), the problem of transmissivity decrease on blue light due to the blue shift of the transmissivity may be mitigated. Taking FIG. 3 as an example, by changing a material, thickness or combination thereof of a high refractive index layer and/or a low refractive index layer in the first band-pass filter 12, the transmissivity of the first band-pass filter 12 may be shifted to a long wavelength. In some embodiments, the first cut-off wavelength WC1 may be greater than the first peak wavelength WP1 of the first conversion light beam C1, and a difference between the first cut-off wavelength WC1 and the first peak wavelength WP1 is less than 10% of the first peak wavelength WP1, i.e., (WC1−WP1)<WP1*10%, in order to balance the transmissivity of the first band-pass filter 12 to the first light beam B1 and the reflectivity of the first band-pass filter 12 to the first conversion light beam C1. The first cut-off wavelength WC1 of the first band-pass filter 12 is defined as a wavelength corresponding to 50% transmissivity or a wavelength corresponding to 50% reflectivity of the first band-pass filter 12 in the visible light waveband.

In some embodiments, a range of the first cut-off wavelength WC1 is 510 nm to 630 nm, i.e., 510 nm≤WC1≤630 nm, but the disclosure is not limited thereto. In some embodiments, the range of the first cut-off wavelength WC1 is 510 nm to 550 nm, i.e., 510 nm≤WC1≤550 nm, but the disclosure is not limited thereto.

Referring to FIG. 1 again, according to different requirements, the display device 1 may further include other elements or film layers. For example, the display device 1 may further include a pixel definition layer 14. The pixel definition layer 14 is disposed on the substrate 10 and surrounds the first light-emitting unit 11. For example, the pixel definition layer 14 may be formed of an opaque material, but the disclosure is not limited thereto, and the pixel definition layer 14 may include an opening A1, and the first light-emitting unit 11 is disposed in the opening A1. The opaque materials may include an organic material, an inorganic material, or a combination thereof.

The display device 1 may further include a bottom filler 15. The bottom filler 15 is disposed in the opening A1 and covers the first light-emitting unit 11. A material of the bottom filler 15 may include liquid epoxy resin, deformable gel, silicon rubber, or similar materials, but the disclosure is not limited thereto.

The display device 1 may further include a substrate 16, a light shielding layer 17, a color filter layer 18, a blocking wall 19, a planarization layer 20 and an adhesive layer 21, but the disclosure is not limited thereto.

The substrate 16 is a light-transmitting substrate. A material of the substrate 16 may include, but not limited to, glass, plastic, ceramic, quartz, sapphire, or a combination thereof.

The light shielding layer 17 is disposed on a surface of the substrate 16 facing the substrate 10 and has an opening A2. The opening A2 at least partially overlaps the opening A1 in a thickness direction (for example, ae direction Z) of the display device 1. A material of the light shielding layer 17 may include black matrix, black photoresist or photoresist of other colors, but the disclosure is not limited thereto.

The color filter layer 18 is disposed on the surface of the substrate 16 facing the substrate 10 and located in the opening A2. The color filter layer 18 may be used to enhance color purity. For example, the color filter layer 18 may include an absorbing color photoresist to let at least a part of the first conversion light beam C1 to pass through and filter light beams of other colors. If there is no filter layer/filter pattern on the first light conversion layer 13, the first conversion light beam C1 is light passing through the first light conversion layer 13. If there is a filter layer/filter pattern on the first light conversion layer 13, the first conversion light beam C1 is light passing through the filter layer/filter pattern.

The blocking wall 19 is disposed on a surface of the light shielding layer 17 facing the substrate 10 and has an opening A3. The opening A3 at least partially overlaps the opening A1 and the opening A2 in the thickness direction (for example, the direction Z) of the display device 1. A material of the blocking wall 19 may include a light absorbing material, such as black photoresist, white photoresist or photoresist of other colors, but the disclosure is not limited thereto. In some embodiments, although not shown, in addition to the light absorbing material, the material of the blocking wall 19 may further include light scattering particles, but the disclosure is not limited thereto. In other embodiments, a material of the blocking wall 19 may include a light-transmitting material (for example, a transparent photoresist) and a reflective layer or a light-absorbing layer disposed on the light-transmitting material.

The first light conversion layer 13 is disposed on a surface of the color filter layer 18 facing the substrate 10 and located in the opening A3. Therefore, the first light conversion layer 13 at least partially overlaps with the color filter layer 18 and the first light-emitting unit 11 in the thickness direction (for example, the direction Z) of the display device 1.

The planarization layer 20 is disposed on a surface of the blocking wall 19 facing the substrate 10 and on a surface of the first light conversion layer 13 facing the substrate 10. The planarization layer 20 may be used to package the first light conversion layer 13 and may also provide a flat surface on which the first band-pass filter 12 is disposed. A material of the planarization layer 20 may include inorganic materials, such as silicon oxide (SiOx), silicon nitride (SiNx), or a combination thereof, but the disclosure is not limited thereto. The material of the planarization layer 20 may also include organic materials, such as acrylic silicon, siloxane silicon or a combination thereof, but the disclosure is not limited thereto. The material of the planarization layer 20 may also be a combination of the above-mentioned inorganic materials and organic materials, but the disclosure is not limited thereto.

The first band-pass filter 12 is disposed on a surface of the planarization layer 20 facing the substrate 10. By using the planarization layer 20 to provide a flat surface on which the first band-pass filter 12 is disposed, the effect of light penetration and/or light reflection of the first band-pass filter 12 is improved.

The adhesive layer 21 is disposed between the first light-emitting unit 11 and the first light conversion layer 13, and the first band-pass filter 12 is, for example, disposed between the adhesive layer 21 and the first light conversion layer 13. For example, the first band-pass filter 12 may be attached to the pixel definition layer 14 and the bottom filler 15 through the adhesive layer 21, but the disclosure is not limited thereto.

Referring to FIG. 5, main differences between a display device 1A and the display device 1 of FIG. 1 are described below. In the display device 1A, the first band-pass filter 12 is disposed between the adhesive layer 21 and the first light-emitting unit 11. For example, the first band-pass filter 12 may be set on the pixel definition layer 14 and the bottom filler 15, and the first band-pass filter 12 may be attached to the planarization layer 20 through the adhesive layer 21.

Referring to FIG. 6, main differences between a display device 1B and the display device 1A of FIG. 5 are described as follows. The display device 1B may not include the bottom filler 15 of FIG. 5, but the disclosure is not limited thereto. The pixel definition layer 14 has a top surface ST and a side surface SS, and the top surface ST is adjacent to the side surface SS, where the first band-pass filter 12 is further disposed on the top surface ST and the side surface SS of the pixel definition layer 14. In addition, the first light-emitting unit 11 has a top surface ST′ and a side surface SS′, and the top surface ST′ is adjacent to the side surface SS′, where the first band-pass filter 12 is further disposed on the top surface ST′ and the side surface SS′ of the first light-emitting unit 11. For example, the first band-pass filter 12 may be formed on the top surface ST and the side surface SS of the pixel definition layer 14 and on the top surface ST′ and the side surface SS′ of the first light-emitting unit 11 by means of coating, but the disclosure is not limited thereto. In addition, the adhesive layer 21 is further disposed in the opening A1 and located between the first light-emitting unit 11 and the substrate 10. In other embodiments, the display device 1B may include the bottom filler 15, and the bottom filler 15 may be, for example, formed after the first band-pass filter 12 is formed, and then the adhesive layer 21 is formed.

Referring to FIG. 7, main differences between a display device 1C and the display device 1A of FIG. 5 are described below. In the display device 1C, the first band-pass filter 12 is disposed on the first light-emitting unit 11 and is not disposed on the pixel definition layer 14 and the bottom filler 15. For example, the first band-pass filter 12 may be first disposed on the first light-emitting unit 11 first, and then the first light-emitting unit 11 is combined with the substrate 10, and then the bottom filler 15 is formed. Under such framework, the first band-pass filter 12, the pixel definition layer 14, and the bottom filler 15 are all in contact with the adhesive layer 21.

Since the first band-pass filter 12 has a light-converging effect, by directly disposing the first band-pass filter 12 on the first light-emitting unit 11, it helps enhancing light intensity of the first light beam transmitted to the first light conversion layer 13, or increasing the light intensity of the display device 1C under normal viewing angle.

Referring to FIG. 8, main differences between a display device 1D and the display device 1C of FIG. 7 are described below. The display device 1D further includes a second band-pass filter 22. The second band-pass filter 22 is disposed between the adhesive layer 21 and the first light conversion layer 13. For example, the second band-pass filter 22 may be disposed on the surface of the planarization layer 20 facing the substrate 10 and bonded to the first band-pass filter 12, the pixel definition layer 14 and the bottom filler 15 through the adhesive layer 21.

The second band-pass filter 22 has a second cut-off wavelength, and the first cut-off wavelength may be greater than the second cut-off wavelength. In detail, the first band-pass filter 12 disposed on the first light-emitting unit 11 may be used to improve collimation of the first light beam transmitted toward the first light conversion layer 13, and the first band-pass filter 12 disposed on the first light-emitting unit 11 may have a larger cut-off wavelength to mitigate the blue shift of transmissivity, so that more first light beams may penetrate through the first band-pass filter 12 and transmitted to the first light conversion layer 13. A divergence angle of the first light beam passing through the first band-pass filter 12 and transmitted toward the second band-pass filter 22 has been converged by the first band-pass filter 12, which reduces a proportion of the first light beam incident to the second band-pass filter 22 at a large angle. Therefore, a red shift degree of the second band-pass filter 22 may be made smaller than that of the first band-pass filter 12, i.e., the second cut-off wavelength is made smaller than the first cut-off wavelength, so as to increase an amount of recovery of the first conversion light beam.

Referring to FIG. 9, main differences between a display device 1E and the display device 1A of FIG. 5 are described as follows. The display device 1E further includes the second band-pass filter 22. Detailed description of the second band-pass filter 22 may be deduced by referring to the above related description, which is not repeated.

Referring to FIG. 10, main differences between a display device 1F and the display device 1A of FIG. 5 are described as follows. The display device 1F further includes a second light-emitting unit 23 and a second light conversion layer 24. The second light-emitting unit 23 is disposed on the substrate 10 and is configured to emit a second light beam (not shown). The second light-emitting unit 23 may be fixed on the substrate 10 by means of soldering, pasting or any other feasible bonding method and is disposed in the opening A1 of the pixel definition layer 14. The second light-emitting unit 23 may be electrically connected to an external circuit (for example, a power source) through a circuit (not shown) on the substrate 10, thereby providing the second light beam. The second light beam and the first light beam may have a same color (for example, both blue), but the disclosure is not limited thereto. The second light-emitting unit 23 may include a light-emitting diode, such as an organic light-emitting diode, a mini light-emitting diode, a micro light-emitting diode or a quantum dot light-emitting diode, but the disclosure is not limited thereto. In some embodiments, the second light-emitting unit 23 may include a light-emitting diode chip. In other embodiments, the second light-emitting unit 23 may include a packaged light-emitting diode, but the disclosure is not limited thereto. The reflector 100 may also be disposed under the second light-emitting unit 23 to deflect the second light beam transmitted toward the substrate 10, so that the second light beam is deflected to the second light conversion layer 24.

The second light conversion layer 24 is, for example, disposed on a surface of the color filter layer 18 facing the substrate 10 and located in the opening A3 of the blocking wall 19. The second light conversion layer 24 is configured to convert the second light beam into a second conversion light beam C2 (referring to FIG. 3). The second conversion light beam C2 is light transmitted to a user through all of the light-emitting structures under the single sub-pixel SP in the single pixel P. The second conversion light beam C2 may be a red beam, a green beam or a blue beam, and a wavelength of the second conversion light beam C2 may be the wavelength corresponding to the red beam, the green beam or the blue beam. If there is no filter layer/filter pattern on the second light conversion layer 24, the second conversion light beam C2 is the light passing through the second light conversion layer 24. If the second light conversion layer 24 is provided with a filter layer/filter pattern, the second conversion light beam C2 is light passing through the filter layer/filter pattern. For example, a wavelength of the second conversion light beam C2 may be 610 nm to 650 nm. The second conversion light beam C2 has a second peak wavelength WP2. The second peak wavelength WP2 refers to a wavelength corresponding to the maximum peak with the highest grayscale (such as 255 grayscale) or the maximum light intensity in the wavelength range (such as 610 nm to 650 nm) of the second conversion light beam C2. The first peak wavelength WP1 is different from the second peak wavelength WP2. In some embodiments, the second light conversion layer 24 may further include light scattering particles 240 to increase a transmission path of the second light beam in the second light conversion layer 24, so that more second light beams may be converted into the second conversion light beam C2 by the wavelength conversion material (referring to FIG. 3), but the disclosure is not limited thereto.

The first band-pass filter 12 may also be disposed on the second light-emitting unit 23. As shown in FIG. 10, the first band-pass filter 12 may be disposed on the pixel definition layer 14 and the bottom filler 15 and cover the first light-emitting unit 11 and the second light-emitting unit 23, but the disclosure is not limited thereto.

In some embodiments, the display device 1F may further include a third light-emitting unit 25 and a light transmitting layer 26. The third light-emitting unit 25 is disposed on the substrate 1F and is configured to emit a third light beam (not shown). The third light-emitting unit 25 may be fixed on the substrate 10 by means of soldering, pasting or any feasible bonding method and disposed in the opening A1 of the pixel definition layer 14. The third light-emitting unit 25 may be electrically connected with an external circuit (such as a power source) through a circuit (not shown) on the substrate 10, thereby providing the third light beam. The third light beam and the first light beam may have a same color (for example, both blue), but the disclosure is not limited thereto. The third light-emitting unit 25 may include a light-emitting diode, such as an organic light-emitting diode, a mini light-emitting diode, a micro light-emitting diode or a quantum dot light-emitting diode, but the disclosure is not limited thereto. In some embodiments, the third light-emitting unit 25 may include a light-emitting diode chip. In other embodiments, the third light-emitting unit 25 may include a packaged light-emitting diode, but the disclosure is not limited thereto. The reflector 100 may also be disposed under the third light-emitting unit 25 to deflect the third light beam transmitted toward the substrate 10, so that the third light beam is deflected to the second light transmitting layer 26.

The light transmitting layer 26 is, for example, disposed on a surface of the color filter layer 18 facing the substrate 10 and located in the opening A3 of the blocking wall 19. The light transmitting layer 26 is pervious to light. For example, a material of the light transmitting layer 26 may include a transparent polymer. In some embodiments, the light transmitting layer 26 may also include light scattering particles 260 to make light patterns of light beams emitted by different color pixels more consistent and reduce a color shift phenomenon caused by inconsistency of the light patterns.

The first band-pass filter 12 may also be disposed on the third light-emitting unit 25. As shown in FIG. 10, in a single pixel P, the first band-pass filter 12 may be disposed on the pixel definition layer 14 and the bottom filler 15 and cover the first light-emitting unit 11, the second light-emitting unit 23, and the third light-emitting unit 25, but the disclosure is not limited thereto. Where, the first light-emitting unit 11, the second light-emitting unit 23 and the third light-emitting unit 25 respectively correspond to a single sub-pixel SP. In other embodiments that are not shown, a setting position of the first band-pass filter 12 may be changed according to FIG. 1, FIG. 6, or FIG. 7. Alternatively, the display device IF may also include the second band-pass filter 22 as shown in FIG. 8 or FIG. 9. The second band-pass filter 22 may be disposed between the adhesive layer 21 and the planarization layer 20 and cover the first light-emitting unit 11, the second light-emitting unit 23, and the third light-emitting unit 25. The first band-pass filter 12 of the following embodiments may all be changed as above, or the display device may further include the second band-pass filter 22 as shown in FIG. 8 or FIG. 9, which is not repeated below.

Although not shown, the display device 1F may include a plurality of first light-emitting units 11, a plurality of second light-emitting units 23, and a plurality of third light-emitting units 25, and these light-emitting units may be arranged on the substrate 10 in an array. In addition, the color filter layer 18 may include a first color filter pattern 180, a second color filter pattern 182, and a third color filter pattern 184 which are at least partially overlapped with the first light conversion layer 13, the second light conversion layer 24, and the light transmitting layer 26 in the direction Z, respectively, so as to improve color purity. In some embodiments, the first light-emitting unit 11, the second light-emitting unit 23 and the third light-emitting unit 25 may have a same color, for example, a blue light-emitting unit. The first light conversion layer 13 and the second light conversion layer 24 may have a color different from the color of the above light-emitting units, for example, a green light conversion layer and a red light conversion layer, respectively, and the first color filter pattern 180, the second color filter pattern 182 and the third color filter pattern 184 may have different colors, for example, respectively a green filter pattern that allows green light to pass through, a red filter pattern that allows red light to pass through, and a blue filter pattern that allows blue light to pass through. Namely, the first light-emitting unit 11, the second light-emitting unit 23, and the third light-emitting unit 25, for example, respectively correspond to a green pixel, a red pixel, and a blue pixel of the display device 1F, but the disclosure is not limited thereto.

Referring to FIG. 11A and FIG. 11B, a display device 1G may include the substrate 10, the first light-emitting unit 11, the second light-emitting unit 23, a band-pass filter 12G, and a light conversion layer 13G. According to different requirements, the display device 1G may further include other elements mentioned above, such as the pixel definition layer 14, the bottom filler 15, the substrate 16, the light shielding layer 17, the color filter layer 18, the blocking wall 19, the planarization layer 20, the adhesive layer 21, the light transmitting layer 26, etc. Details of these elements or layers may be deduced by referring to the above description, which will not be repeated here.

In the display device 1G, the first light beam B1 (or the third light beam B3) emitted by the first light-emitting unit 11 (or the third light-emitting unit 25) and the second light beam B2 emitted by the second light-emitting unit 23 have different colors. For example, the first light-emitting unit 11 and the third light-emitting unit 25 are blue light-emitting units, and the first light beam B1 and the third light beam B3 are blue, and the second light-emitting unit 23 is a green light-emitting unit, and the second light beam B2 is green.

The second light beam B2 has a first peak wavelength WP1. The band-pass filter 12G is disposed on the first light-emitting unit 11, the second light-emitting unit 23 and the third light-emitting unit 25 and has a cut-off wavelength WC. A curve L10 in FIG. 11B represents the transmissivity of the band-pass filter 12G to light incident (for example, normal incidence) to the band-pass filter 12G in the visible light waveband. The light conversion layer 13G is disposed on the band-pass filter 12G and is configured to convert the first light beam B1 into the first conversion light beam C1. The first conversion light beam C1 has a second peak wavelength WP2, and the cut-off wavelength WC is between the first peak wavelength WP1 and the second peak wavelength WP2. Taking FIG. 11B as an example, the light conversion layer 13G, for example, converts blue light (the first light beam B1) into red light (the first conversion light beam C1), and the cut-off wavelength WC is between green light and red light. In some embodiments, the cut-off wavelength WC ranges from 560 nm to 630 nm, i.e., 560 nm≤WC≤630 nm, but the disclosure is not limited thereto. In some embodiments, the cut-off wavelength WC ranges from 580 nm to 600 nm, i.e., 580 nm≤WC≤600 nm, but the disclosure is not limited thereto.

In the embodiment, the band-pass filter 12G is designed to let the first light beam B1 and the second light beam B2 to pass through and reflect at least a part of the first conversion light beam C1, where the cut-off wavelength WC is greater than the first peak wavelength WP1 and less than the second peak wavelength WP2, and a difference between the cut-off wavelength WC and the second peak wavelength WP2 is, for example, less than 10% of the second peak wavelength WP2, for example, (WP2−WC)<WP2*10%.

By making the transmissivity of the band-pass filter 12G red shift, for example, by making the cut-off wavelength WC falling within a spectrum range of the first conversion light beam C1, it helps to mitigate the problem of transmissivity reduction to blue light caused by blue shift of the transmissivity, and further helps improving the light conversion efficiency of red light.

In the display device 1G, the first light-emitting unit 11, the second light-emitting unit 23 and the third light-emitting unit 25, for example, respectively correspond to a red pixel, a green pixel and a blue pixel of the display device 1G. In the green pixel, the second light-emitting unit 23 emitting green light in collaboration with the light transmitting layer 26 are used to replace the second light-emitting unit 23 emitting blue light in collaboration with the second light conversion layer 24 in FIG. 10.

Referring to FIG. 12A and FIG. 12B, a main difference between a display device 1H and the display device 1G in FIG. 11A is that a light transmitting layer 26H in the display device 1H does not include the light scattering particles 260 of FIG. 11A. As shown in FIG. 12B, a curve L11 represents light intensity of the first light beam not passing through the band-pass filter 12G at different zenith angles (angle θ), and a curve L12 represents light intensity of the first light beam passing through the band-pass filter 12G at different zenith angles. It may be seen from FIG. 12B that the band-pass filter 12G helps improving light intensity at a normal viewing angle (the angle θ is around 0 degree), and the band-pass filter 12G has a centralized brightening effect. Therefore, by configuring the band-pass filter 12G and using the light transmitting layer 26H without light scattering particles, directivity and brightness of the display device 1H may be improved or an anti-peep effect, etc., may be provided. Regarding the light conversion layer 13G, by configuring the light scattering particles 130, the light path of the first light beam coming from the first light-emitting unit 11 in the light conversion layer 13G may be increased to excite more first conversion light beams.

In summary, in the embodiments of the disclosure, by configuring the band-pass filter to improve light usage rate or light conversion efficiency, and through the design that the difference between the first cut-off wavelength and the first peak wavelength is less than 10% of the first peak wavelength, transmissivity of the band-pass filter to the first light beam and reflectivity of the band-pass filter to the first conversion light beam are balanced.

The above embodiments are only used to explain the disclosed technical solutions, not for limiting; although the disclosure is described in detail with reference to the aforementioned embodiments, those skilled in the art should understand that they may still modify the technical solutions recorded in the aforementioned embodiments, or replace some or all of the technical features equally; these modifications or substitutions do not make an essence of the corresponding technical solution departing from a scope of the technical solutions of the embodiments of the disclosure.

Although the embodiments and advantages of the disclosure have been disclosed as above, it should be understood that any person with general knowledge in the technical field may make changes, substitutions and embellishments without departing from the spirit and scope of the disclosure, and the features of the embodiments may be arbitrarily mixed and replaced to form other new embodiments. In addition, a protection scope of the disclosure is not limited to the processes, machines, manufacturing, material compositions, devices, methods and steps in the specific embodiments described in the specification. Anyone with general knowledge in the technical field may understand the current or future developed processes, machines, manufacturing, material compositions, devices, methods and steps from the content disclosed by the disclosure, which may all be used according to the disclosure as long as the same functions may be implemented or the same results may be obtained in the embodiments described herein. Therefore, the protection scope of the disclosure includes the above processes, machines, manufacturing, material compositions, devices, methods and steps. In addition, each claim constitutes an individual embodiment, and the protection scope of the disclosure also includes a combination of each claim and the embodiments. The protection scope of the disclosure shall be subject to the following claims.

What is claimed is:

1. A display device, comprising:
a substrate;
a first light-emitting unit, disposed on the substrate and configured to emit a first light beam;
a first band-pass filter, disposed on the first light-emitting unit and having a first cut-off wavelength; and
a first light conversion layer, disposed on the first band-pass filter and configured to convert the first light beam into a first conversion light beam, wherein the first conversion light beam has a first peak wavelength, and a difference between the first cut-off wavelength and the first peak wavelength is less than 10% of the first peak wavelength.

2. The display device according to claim 1, wherein the first cut-off wavelength is greater than the first peak wavelength.

3. The display device according to claim 1, wherein the first cut-off wavelength ranges from 510 nm to 630 nm.

4. The display device according to claim 3, wherein the first cut-off wavelength ranges from 510 nm to 550 nm.

5. The display device according to claim 1, further comprising:
an adhesive layer, disposed between the first light-emitting unit and the first light conversion layer.

6. The display device according to claim 5, wherein the first band-pass filter is disposed between the adhesive layer and the first light conversion layer.

7. The display device according to claim 5, wherein the first band-pass filter is disposed between the adhesive layer and the first light-emitting unit.

8. The display device according to claim 7, further comprising:
a second band-pass filter, disposed between the adhesive layer and the first light conversion layer.

9. The display device according to claim 8, wherein the second band-pass filter has a second cut-off wavelength, and the first cut-off wavelength is greater than the second cut-off wavelength.

10. The display device according to claim 1, further comprising:
a pixel definition layer, disposed on the substrate and surrounding the first light-emitting unit.

11. The display device according to claim 10, wherein the pixel definition layer has a top surface and a side surface, and the top surface is adjacent to the side surface, wherein the first band-pass filter is further disposed on the top surface and the side surface of the pixel definition layer.

12. The display device according to claim 1, further comprising:
a second light-emitting unit, disposed on the substrate and configured to emit a second light beam; and
a second light conversion layer, configured to convert the second light beam into a second conversion light beam, wherein the second conversion light beam has a second peak wavelength, the first peak wavelength is different from the second peak wavelength, and the first band-pass filter is further disposed on the second light-emitting unit.

13. A display device, comprising:
a substrate;
a first light-emitting unit, disposed on the substrate and configured to emit a first light beam;
a second light-emitting unit, disposed on the substrate and configured to emit a second light beam, wherein the first light beam and the second light beam have different colors, and the second light beam has a first peak wavelength;
a band-pass filter, disposed on the first light-emitting unit and the second light-emitting unit and having a cut-off wavelength; and
a light conversion layer, disposed on the band-pass filter and configured to convert the first light beam into a first conversion light beam, wherein the first conversion light beam has a second peak wavelength, and the cut-off wavelength is between the first peak wavelength and the second peak wavelength.

14. The display device according to claim 13, wherein the cut-off wavelength ranges from 560 nm to 630 nm.

15. The display device according to claim 14, wherein the cut-off wavelength ranges from 580 nm to 600 nm.

16. The display device according to claim 13, wherein the first light beam is blue.

17. The display device according to claim 13, wherein the second light beam is green.

18. The display device according to claim 13, further comprising:
a light transmitting layer, disposed on the band-pass filter and overlapped with the second light-emitting unit, wherein the light transmitting layer allows the second light beam to pass through.

19. The display device according to claim 18, wherein the light transmitting layer comprises light scattering particles.

20. The display device according to claim 13, further comprising:
a third light-emitting unit, disposed on the substrate and configured to emit a third light beam, wherein the first light beam and the third light beam have a same color, and the band-pass filter is further disposed on the third light-emitting unit; and
another light transmitting layer, disposed on the band-pass filter and overlapped with the third light-emitting unit, wherein the another light transmitting layer allows the third light beam to pass through.
